(19) United States
(12) Patent Application Publication
(10) Pub. No.: US 2012/0026802 A1
(43) Pub. Date: Feb. 2, 2012

(54) MANAGED HYBRID MEMORY WITH ADAPTIVE POWER SUPPLY

(76) Inventor: Emanuele Confalonieri, Lesmo (Milano) (IT)

(21) Appl. No.: 12/847,807

(22) Filed: Jul. 30, 2010

(51) Int. Cl. G11C 7/00

(52) U.S. Cl. 365/189.2; 365/189.11

(57) ABSTRACT

Subject matter disclosed herein relates to a memory device, and more particularly to a managed hybrid memory that includes a power supply.

### BACKGROUND

1. Field:

Subject matter disclosed herein relates to a memory device, and more particularly to a managed hybrid memory that includes a power supply.

2. Information:

Memory devices are employed in many types of electronic devices, such as computers, cell phones, PDA's, data loggers, and navigational equipment, just to name a few examples. Among such electronic devices, various types of volatile or nonvolatile memory devices may be employed, such as NAND or NOR flash memories, SRAM, DRAM, and phase-change memory, just to name a few examples. Each type of memory technology has particular strong points and weak points with respect to various applications. In other words, such types of memory technologies may be more suited to particular applications than other types of memory technologies.

### BRIEF DESCRIPTION OF THE FIGURES

Non-limiting and non-exhaustive embodiments will be described with reference to the following figures, wherein like reference numerals refer to like parts throughout the various figures unless otherwise specified.

FIGS. 1-4 are schematic block diagrams of hybrid memories, according to several embodiments.

FIG. 5 is a schematic diagram illustrating an exemplary embodiment of a computing system.

FIG. 6 shows voltage converters and associated gain plots, according to an embodiment.

### DETAILED DESCRIPTION

Reference throughout this specification to “one embodiment” or “an embodiment” means that a particular feature, structure, or characteristic described in connection with the embodiment is included in at least one embodiment of claimed subject matter. Thus, the appearances of the phrase “in one embodiment” or “an embodiment” in various places throughout this specification are not necessarily all referring to the same embodiment. Furthermore, the particular features, structures, or characteristics may be combined in one or more embodiments.

Embodiments described herein involve managed hybrid memory comprising two or more memory technologies. Herein, memory technology refers to the type of technology on which a memory or family of memories may be based. For example, different memory technologies may be based on different memory cell configurations (e.g., SRAM memory cell comprising six transistors, DRAM memory cell comprising one transistor and a capacitor). In another example, different memory technologies may be based on whether different memories are volatile or nonvolatile. Other examples of memory technologies include, but are not limited to, NOR, NAND, Flash, phase change memory (PCM), NAND multi-level cell (MLC) memory, NAND single-level cell (SLC) memory, and so on. As discussed in further detail below, such different memory technologies may operate using substantially different voltages. Herein, the term “substantially different voltages” may refer to voltages that differ by more than about 5-10%. For example, one memory technology may operate using 5.0 volts while another memory technology may operate using a substantially different voltage comprising 4.5 volts, though claimed subject matter is not so limited. Herein, the term “substantially different voltages” may also refer to two voltages that differ by an amount that is enough to allow a particular memory technology to operate using only one of the two (but not both) voltages. For example, a NAND MLC memory device may operate using 3.0 volts while a NAND SLC memory device may operate using 1.8 volts. Of course, such details of memory devices are merely examples, and claimed subject matter is not so limited.

As mentioned above, two or more memory technologies may operate using voltage levels different from one another. For example, a managed hybrid memory may comprise a first memory device that operates using 3.0 volts and a second memory device that operates using 1.8 volts, though claimed subject matter is not so limited. To accommodate such different operating voltage levels, a managed hybrid memory may comprise an adaptive power supply to provide the different operating voltages to individual memory devices within the managed hybrid memory. In an implementation, such an adaptive power supply may comprise a voltage converter, as discussed in detail below. A managed hybrid memory may include a controller to operate such individual memory devices within the managed hybrid memory. In one implementation, a voltage converter may be integrated with and operated by the controller. In another implementation, a voltage converter may be separate from the controller and located in a different portion of a managed hybrid memory. It should be understood, however, that these are merely example implementations of a managed hybrid memory, and claimed subject matter is not limited in this respect.

Managed hybrid memory may be useful for providing multiple operating characteristics that may not otherwise be available by using only one memory technology. For example, a hybrid managed memory may comprise a NOR memory device and a NAND memory device, thus providing benefits that each such memory device technology may have to offer. Another example of a hybrid managed memory may comprise a NAND MLC device and a NAND SLC device. Yet another example of a hybrid managed memory may comprise a NAND MLC device and a PCM device. It should be noted that any number and combination of memory technologies, in addition to those cited herein, may be included in a managed hybrid memory. Of course, such cited examples are merely presented here for illustrative purposes, and claimed subject matter is not so limited.

As mentioned above, multiple memory devices comprising different memory technologies incorporated in a hybrid managed memory may operate using voltages different from one another. Hybrid managed memory may comprise an input port to receive a power supply signal from an external source (e.g., external with respect to the hybrid managed memory). In one implementation, a first memory device included in a hybrid memory may operate using a voltage that is substantially the same as that of the power supply signal from the external source. In contrast, a second memory device included in the hybrid memory may operate using a voltage that is different from that of the power supply signal. Accordingly, an adaptive power supply may be incorporated into a managed hybrid memory to provide proper voltages to multiple memory devices within the managed hybrid memory. Such an adaptive power supply may comprise a voltage converter to convert a portion of the power supply signal to provide a signal having a voltage that may be used by the second memory device. In another implementation, both first and second memory devices included in a hybrid memory may operate using a voltage that is different from that of the power supply signal. Accordingly, a voltage converter may be used to convert at least a portion of the power supply signal to provide two or more signals having different voltages that may be used by the first and second memory devices.

In an embodiment, a voltage converter used in a managed hybrid memory may comprise a step-up converter to boost the voltage of an input signal. That is, a step-up converter may produce an output signal having a voltage higher than that of an input signal. On the other hand, a voltage converter used in a managed hybrid memory may comprise a step-down converter to reduce the voltage of an input signal. That is, a step-down converter may produce an output signal having a voltage lower than that of an input signal. Such voltage converters may be implemented using any of a number of designs. Such voltage converters may comprise DC-DC voltage converters, which receive a DC input voltage signal and produce a (lower or higher) DC output voltage signal. In addition to ability to increase or decrease the magnitude of an input DC voltage signal, such voltage converters may also invert the polarity (e.g., positive/negative) of the input DC voltage signal. Of course, such details of a voltage converter are merely examples, and claimed subject matter is not so limited.

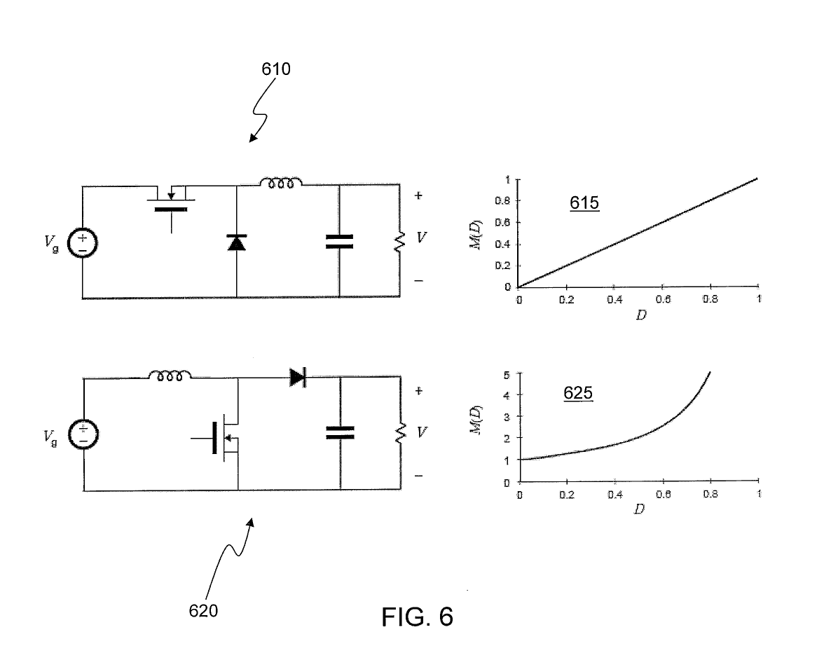

FIG. 6 shows schematic diagrams of examples of voltage converters and associated gain plots, according to an embodiment. Voltage converter 610 may comprise a buck converter (e.g., step-down converter) to produce an output signal having a voltage lower than that of an input signal. Plot 615 illustrates amplification M(D) as a function of clock duty cycle D. Amplification M(D) may comprise a gain ratio V/Vg, e.g., the ratio of input voltage to output voltage, as shown in FIG. 6. Accordingly, gain plot 615 shows that amplification M(D) may be less than 1.0 so that output voltage is less than input voltage.

Voltage converter 620 may comprise a boost converter (e.g., step-up converter) to produce an output signal having a voltage higher than that of an input signal. Plot 625 illustrates amplification M(D) as a function of clock duty cycle D. Amplification M(D) may comprise the gain ratio V/Vg, as shown in FIG. 6. Accordingly, gain plot 625 shows that amplification M(D) may be greater than 1.0 so that output voltage is greater than input voltage. Though not shown in FIG. 6, a voltage converter may comprise circuitry including inductive and/or capacitive energy storage components, wherein DC-DC conversion may be based, at least in part, on switched-capacitor techniques, for example.

It should be noted that a voltage converter may increase or decrease an input voltage substantially without consuming power. In other words, a voltage converter need not comprise resistive components that result in ohmic losses. In contrast, a voltage divider may comprise a number of resistive components that lose energy while providing a decreased output voltage (e.g., compared to an input voltage). Accordingly, a voltage converter, as described herein, is not to be confused with other types of voltage-modifying circuitry that may lose energy during operation, such as a resistance-based voltage divider, for example. In particular implementations, incorporating a voltage converter in a managed hybrid memory may provide a benefit of efficiently supplying different operating voltages to two or more memory devices having different memory technologies within the managed hybrid memory. In other words, an input voltage may be converted to a number of different voltages without involving a substantial loss of power or ohmic heating. It is noted that some embodiments may include resistive elements. Accordingly, implementation of a voltage converter need not preclude the use of resistive elements, and claimed subject matter is not limited in this respect.

FIG. 1 is a schematic block diagram of a managed hybrid memory 100, according to an embodiment. Such a memory may comprise two or more memory devices having different memory technologies, as discussed above. In particular, managed hybrid memory 100 may include a first memory device 120 having a first memory technology and a second memory device 130 having a second memory technology. A controller 110 may receive and/or provide information via line 108 from/to an external source such as a processor, for example. Such information may include read, write, and/or erase commands (e.g., memory access commands), memory addresses, information to be stored in first and/or second memory devices 120 and 130, and so on. Controller 110 may manage first and second memory devices 120 and 130 by selectively providing memory access commands and associated information (e.g., memory addresses and/or information to be stored) to the first and second memory devices, for example. Managed hybrid memory 100 may include a power supply port 105 to receive power from an external source (e.g., a source located outside the managed hybrid memory). Such power may be in the form of a signal having a substantially constant [e.g., direct current (DC)] voltage level, though claimed subject matter is not so limited. In a particular implementation, memory device 120 may operate using a voltage that is substantially the same as that of the power signal provided at power supply port 105. Accordingly, a portion of the power supply signal may be provided to memory device 120 via node 103. On the other hand, memory device 130 may operate using a voltage that is substantially different from that of the power signal provided at power supply port 105. Accordingly, a portion of the power supply signal at node 103 may be provided to a voltage converter 140 to produce a modified power supply signal having a voltage that corresponds to operating specifications of memory device 130. Such a modified power supply signal may comprise a voltage that is greater than or less than that of the power supply signal at node 103. Such a modified power supply signal may subsequently be provided to memory device 130. In one implementation, voltage converter 140 may comprise any of a number of possible circuit configurations, such as voltage converters 610 or 620 shown in FIG. 6, for example. Voltage converter 140 may reside on a portion of a substrate used to fabricate managed hybrid memory 100. Voltage converter 140 may comprise a die that is fabricated in a process that is separate from a process to fabricate the managed hybrid memory 100. In another implementation, voltage converter 140 may comprise a die that is fabricated in a process to simultaneously fabricate at least a portion of the voltage converter 140. To give an example of memory technologies, memory device 120 may comprise a NAND MLC memory device and memory device 130 may comprise a NAND SLC memory device. In such a case, a power supply signal at power supply port 105 may comprise 3.0 volts while voltage converter 140 may produce a modified power supply signal comprising 1.8 volts. Of course, such details of a managed hybrid memory are merely examples, and claimed subject matter is not so limited.

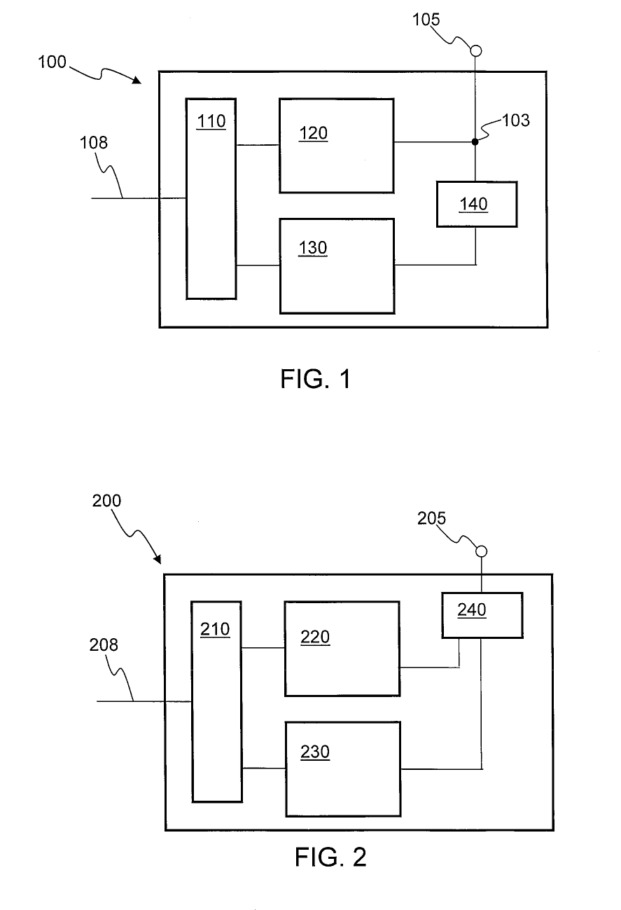

FIG. 2 is a block diagram of a managed hybrid memory 200, according to an embodiment. Similar to managed hybrid memory 100, such a memory may comprise two or more memory devices having different memory technologies. In particular, managed hybrid memory 200 may include a first memory device 220 having a first memory technology and a second memory device 230 having a second memory technology. A controller 210 may receive and/or provide information via line 208 from/to an external source such as a processor, as explained above. Controller 210 may manage first and second memory devices 220 and 230 by selectively providing memory access commands and associated information to the first and second memory devices, for example. Managed hybrid memory 200 may include a power supply port 205 to receive power from an external source. Such power may be in the form of a signal having a substantially constant voltage level, though claimed subject matter is not so limited. In a particular implementation, memory device 220 may operate using a voltage that is substantially different from that of the power signal provided at power supply port 205. Similarly, memory device 230 may operate using a voltage that is substantially different from that of the power signal provided at power supply port 205 and from that used by memory device 220. Accordingly, the power supply signal received at power supply port 205 may be provided to a voltage converter 240 to produce one or more modified power supply signals having voltages that correspond to operating specifications of memory devices 220 and 230. Such modified power supply signals may comprise voltages that are greater than and/or less than that of the power supply signal at power supply port 205. Such modified power supply signals may subsequently be provided to memory devices 220 and 230. To give an example, memory device 220 may comprise a NAND MLC memory device and memory device 230 may comprise a PCM device. In such a case, a power supply signal at power supply port 205 may comprise 2.5 volts while voltage converter 140 may produce modified power supply signals comprising 1.8 volts and 3.0 volts. In another implementation, memory devices 220 and 230 may operate using the same power supply voltage. In such a case, voltage converter 240 may provide such a power supply voltage to memory devices 220 and 230. Of course, such details of a managed hybrid memory are merely examples, and claimed subject matter is not so limited.

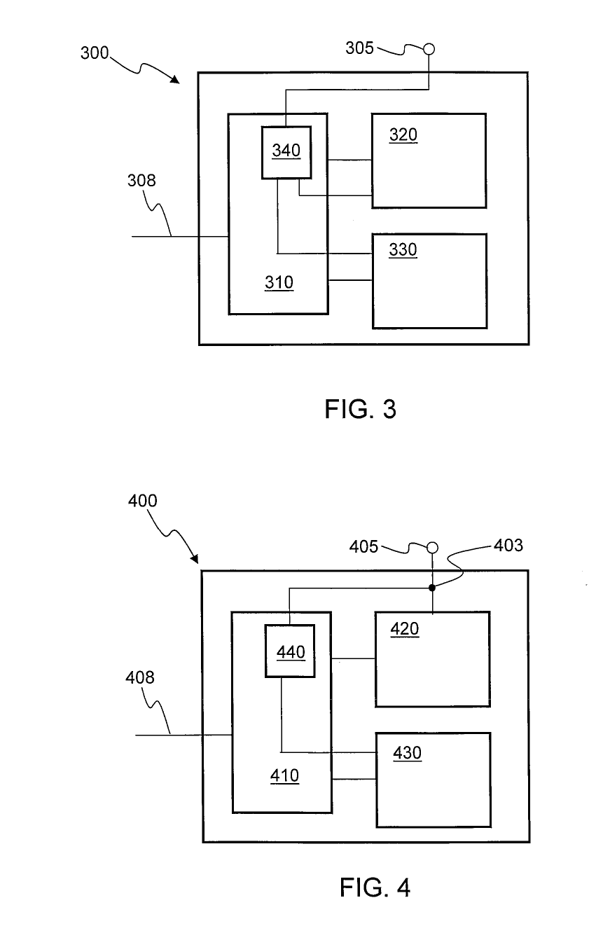

FIG. 3 is a schematic block diagram of a managed hybrid memory 300, according to an embodiment. Similar to managed hybrid memory 100, such a memory may comprise two or more memory devices having different memory technologies. In particular, managed hybrid memory 300 may include a first memory device 320 having a first memory technology and a second memory device 330 having a second memory technology. A controller 310 may receive and/or provide information via line 308 from/to an external source such as a processor, as explained above. Controller 310 may manage first and second memory devices 320 and 330 by selectively providing memory access commands and associated information to the first and second memory devices, for example. Managed hybrid memory 300 may include a power supply port 305 to receive power from an external source. Such power may be in the form of a signal having a substantially constant voltage level, though claimed subject matter is not so limited. In a particular implementation, memory device 320 may operate using a voltage that is substantially different from that of the power signal provided at power supply port 305. Similarly, memory device 330 may operate using a voltage that is substantially different from that of the power signal provided at power supply port 305 and from that used by memory device 320. Accordingly, the power supply signal received at power supply port 305 may be provided to a voltage converter 340 to produce one or more modified power supply signals having voltages that correspond to operating specifications of memory devices 320 and 330. In an implementation, voltage converter 340 may be integrated with controller 310. Such integration may provide a benefit in reducing the number of semiconductor die to be stacked, thereby reducing integrated circuit package complexity, for example. Such a case contrasts with embodiments shown in FIGS. 1 and 2, wherein voltage converters 140 and 240 may comprise a semiconductor die separate from controllers 110 and 210, respectively. Voltage converter 340 may comprise a die that is fabricated by a process that is separate from a process to fabricate the managed hybrid memory 300. In such a case, however, voltage converter 340 may comprise a die that is fabricated by a process that simultaneously fabricates at least a portion of controller 310.

As discussed above, voltage converter 340 may produce modified power supply signals comprising voltages that are greater than and/or less than that of the power supply signal at power supply port 305. Such modified power supply signals may subsequently be provided to memory devices 320 and 330. To give an example, memory device 320 may comprise a NAND MLC memory device and memory device 330 may comprise a PCM device. In such a case, a power supply signal at power supply port 305 may provide 1.5 volts while voltage converter 340 may produce modified power supply signals providing 1.8 volts and 3.0 volts. In another implementation, as mentioned above, memory devices 320 and 330 may operate using the same power supply voltage. In such a case, voltage converter 340 may provide such a power supply voltage to memory devices 320 and 330. Of course, such details of a managed hybrid memory are merely examples, and claimed subject matter is not so limited.

FIG. 4 is a schematic block diagram of a managed hybrid memory 400, according to an embodiment. As in the case for managed hybrid memory 100 discussed above, such a memory may comprise two or more memory devices having different memory technologies, as discussed above. In particular, managed hybrid memory 400 may include a first memory device 420 having a first memory technology and a second memory device 430 having a second memory technology. A controller 410 may receive and/or provide information via line 408 from/to an external source such as a processor, for example. Controller 410 may manage first and second memory devices 420 and 430 by selectively providing memory access commands and associated information. Managed hybrid memory 400 may include a power supply port 405 to receive power from an external source. Such power may be in the form of a signal having a substantially constant voltage level, though claimed subject matter is not so limited. In a particular implementation, memory device 420 may operate using a voltage that is substantially the same as that of the power signal provided at power supply port 405. Accordingly, a portion of the power supply signal may be provided to memory device 420 via node 403. On the other hand, memory device 430 may operate using a voltage that is substantially different from that of the power signal provided at power supply port 405. Accordingly, a portion of the power supply signal at node 403 may be provided to a voltage converter 440 to produce a modified power supply signal having a voltage that corresponds to operating specifications of memory device 430. Unlike managed hybrid memories 100 and 200 shown in FIG. 1, voltage converter 440 may be integrated with controller 410. Such a modified power supply signal may provide a voltage that is greater than or less than that of the power supply signal at node 403. Such a modified power supply signal may subsequently be provided to memory device 430 via controller 410. To give an example, memory device 420 may comprise a NAND MLC memory device and memory device 430 may comprise a NAND SLC memory device. In such a case, a power supply signal at power supply port 405 may provide 3.0 volts while voltage converter 440 may produce a modified power supply signal providing 1.8 volts. Of course, such details of a managed hybrid memory are merely examples, and claimed subject matter is not so limited.

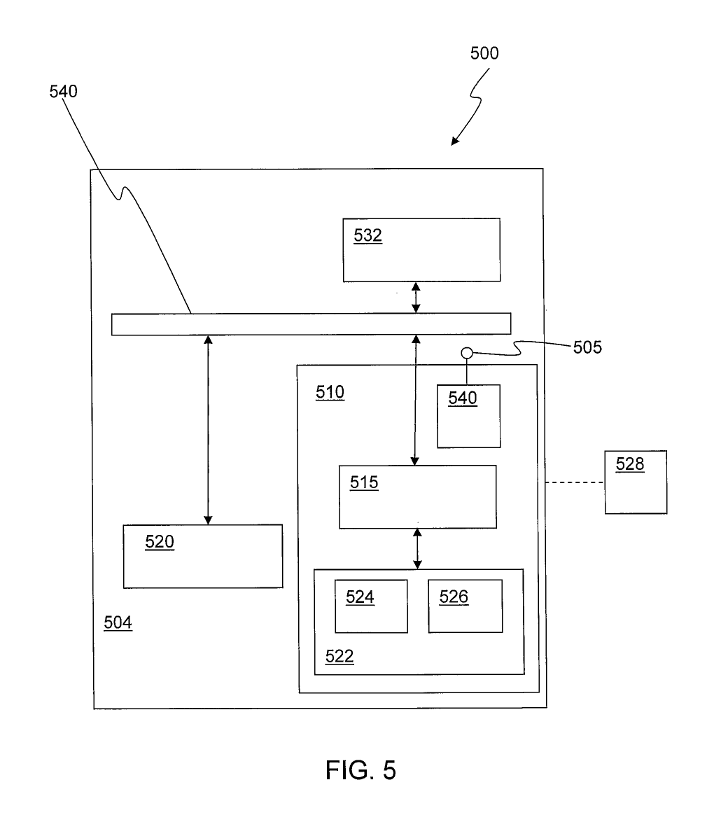

FIG. 5 is a schematic diagram illustrating an exemplary embodiment of a computing system 500 including a memory device 510. Such a computing device may comprise one or more processors, for example, to execute an application and/or other code. A computing device 504 may be representative of any device, appliance, or machine that may be configurable to manage memory device 510. Memory device 510 may include a memory controller 515 and a memory 522. By way of example but not limitation, computing device 504 may include: one or more computing devices and/or platforms, such as, e.g., a desktop computer, a laptop computer, a workstation, a server device, or the like; one or more personal computing or communication devices or appliances, such as, e.g., a personal digital assistant, mobile communication device, or the like; a computing system and/or associated service provider capability, such as, e.g., a database or data storage service provider/system; and/or any combination thereof.

It is recognized that all or part of the various devices shown in system 500, and the processes and methods as further described herein, may be implemented using or otherwise including hardware, firmware, software, or any combination thereof. Thus, by way of example but not limitation, computing device 504 may include at least one processing unit 520 that is operatively coupled to memory 522 through a bus 540 and a host or memory controller 515. Processing unit 520 is representative of one or more circuits configurable to perform at least a portion of a data computing procedure or process. By way of example but not limitation, processing unit 520 may include one or more processors, controllers, microprocessors, microcontrollers, application specific integrated circuits, digital signal processors, programmable logic devices, field programmable gate arrays, and the like, or any combination thereof. Processing unit 520 may include an operating system configured to communicate with memory controller 515. Such an operating system may, for example, generate commands to be sent to memory controller 515 over bus 540. In one implementation, memory controller 515 may comprise an internal memory controller or an internal write state machine, wherein an external memory controller (not shown) may be external to memory device 510 and may act as an interface between the system processor and the memory itself, for example. Such commands may comprise read and/or write commands.

Memory 510 is representative of any data storage mechanism. Memory 510 may include, for example, a managed hybrid memory, such as managed hybrid memory 100 shown in FIG. 1. In an implementation, memory 522 may include primary memory 524 and/or a secondary memory 526. Primary memory 524 may comprise PCM, for example, while secondary memory 526 may comprise a NAND memory. While illustrated in this example as being separate from processing unit 520, it should be understood that all or part of primary memory 524 may be provided within or otherwise co-located/coupled with processing unit 520.

In one embodiment, computing system 500 may comprise managed hybrid memory device 510 comprising first memory device 524 having a first memory technology, a second memory device 526 having a second memory technology different from the first memory technology, and a voltage converter 540 to provide a first voltage to the first memory device and a second voltage to the second memory device, wherein the second voltage is different from the first voltage. In an implementation, voltage converter 540 may receive a power supply signal from node 505, which may be selectively connected to an external power supply, as mentioned above. System 500 may also include controller 515 to apply memory access operations to first and second memory devices in response to read/write/erase operations. System 500 may further include processor 520 to host one or more applications and to initiate read/write/erase operations to provide access to the first and second memory device.

Secondary memory 526 may include, for example, the same or similar type of memory as primary memory and/or one or more data storage devices or systems, such as, for example, a disk drive, an optical disc drive, a tape drive, a solid state memory drive, etc. In certain implementations, secondary memory 526 may be operatively receptive of, or otherwise configurable to couple to, a computer-readable medium 528. Computer-readable medium 528 may include, for example, any medium that can carry and/or make accessible data, code, and/or instructions for one or more of the devices in system 500.

Computing device 504 may include, for example, an input/output 532. Input/output 532 is representative of one or more devices or features that may be configurable to accept or otherwise introduce human and/or machine inputs, and/or one or more devices or features that may be configurable to deliver or otherwise provide for human and/or machine outputs. By way of example but not limitation, input/output device 532 may include an operatively configured display, speaker, keyboard, mouse, trackball, touch screen, data port, etc.

While there has been illustrated and described what are presently considered to be example embodiments, it will be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter not be limited to the particular embodiments disclosed, but that such claimed subject matter may also include all embodiments falling within the scope of the appended claims, and equivalents thereof.

What is claimed is:

1. A managed hybrid memory device comprising:
a first memory device comprising a first memory technology;
a second memory device comprising a second memory technology different from said first memory technology; and
a voltage converter to provide a first voltage to said first memory device and a second voltage to said second memory device, wherein said second voltage is different from said first voltage.

2. The managed hybrid memory device of claim 1, further comprising:
a memory controller adapted to manage said first and second memory devices.

3. The managed hybrid memory device of claim 1, further comprising:
an input port to provide an external signal comprising a single DC voltage to said voltage converter.

4. The managed hybrid memory device of claim 1, wherein said voltage converter comprises a step-up converter or a step-down converter.

5. The managed hybrid memory device of claim 1, wherein said voltage converter comprises a step-up converter and a step-down converter.

6. The managed hybrid memory device of claim 1, wherein said voltage converter exists in said memory controller.

7. The managed hybrid memory device of claim 1, wherein said first memory device comprises a phase change memory and said second memory device comprises a NAND memory.

8. A method comprising:
managing two or more memory technologies in a single integrated circuit package;
converting a first voltage to a second voltage; and
providing said first voltage to a first memory device and said second voltage to a second memory device, wherein said first memory device comprises a memory technology different from that of said second memory device, and wherein said first voltage is different from said second voltage.

9. The method of claim 8, wherein said managing is performed from within said single integrated circuit package.

10. The method of claim 8, further comprising:
receiving an external signal having said first voltage; and
providing said external signal to a voltage converter that exists in said single integrated circuit package.

11. The method of claim 8, wherein said single integrated circuit package comprises a managed hybrid memory.

12. The method of claim 8, wherein said second voltage is greater than said first voltage.

13. The method of claim 8, wherein said first memory device comprises a phase change memory and said second memory device comprises a NAND memory.

14. A system comprising:
a managed hybrid memory device comprising:
a first memory device comprising a first memory technology;
a second memory device comprising a second memory technology different from said first memory technology; and
a voltage converter to provide a first voltage to said first memory device and a second voltage to said second memory device, wherein said second voltage is different from said first voltage; and
a processor to host one or more applications and to initiate read and/or write operations to provide access to said first memory device and said second memory device.

15. The system of claim 14, further comprising:
a memory controller adapted to manage said first and second memory devices and to perform said read and/or write operations.

16. The system of claim 14, further comprising:
an input port to provide an external signal comprising a single DC voltage to said voltage converter.

17. The system of claim 14, wherein said voltage converter comprises a step-up converter or a step-down converter.

18. The system of claim 14, wherein said voltage converter comprises a step-up converter and a step-down converter.

19. The system of claim 14, wherein said voltage converter exists in said memory controller.

20. The system of claim 14, wherein said first memory device comprises a phase change memory and said second memory device comprises a NAND memory.
